(19) United States
(12) Patent Application Publication
(10) Pub. No.: US 2026/0250521 A1
(43) Pub. Date: Aug. 27, 2026

(54) PROTECTIVE FILM, OPTICAL ARTICLE INCLUDING THE SAME, AND METHOD FOR PREPARING THE PROTECTIVE FILM

(71) Applicant: ELECTRONICS AND TELECOMMUNICATIONS RESEARCH INSTITUTE, Daejeon (KR)

(72) Inventor: Woo Seok YANG, Daejeon (KR)

(21) Appl. No.: 19/535,417

(22) Filed: Feb. 10, 2026

(30) Foreign Application Priority Data
Feb. 21, 2025 (KR) 10-2025-0023152
Feb. 2, 2026 (KR) 10-2026-0020821

(51) Int. Cl. C09D 5/16; C08G 18/34; C08G 18/78; C08G 18/79; C08K 9/06; C09D 7/40; C09D 7/62; C09D 175/02; H05K 5/03

(52) U.S. Cl. CPC C09D 5/1625; C08G 18/346; C08G 18/7831; C08G 18/792; C08G 18/798; C09D 5/1662; C09D 7/62; C09D 7/67; C09D 7/70; C09D 175/02; H05K 5/03; C08K 9/06; C08K 2201/011; C08K 2201/014

(57) ABSTRACT

Provided is a protective film including a substrate including a first surface and a second surface facing each other, and a film portion disposed on the first surface, wherein the film portion includes first particles and an organic compound that interconnects the first particles, each of the first particles includes a first inorganic particle and a first bonding compound and a first hydrophobic compound disposed on a surface of the first inorganic particle, the organic compound includes an aliphatic polyisocyanate, the first bonding compound is selected from the group consisting of a compound having a secondary amine group, a compound having an imine group, and a combination thereof, the first hydrophobic compound is selected from the group consisting of a compound having a methyl group, a compound having a trifluoromethyl group, and a combination thereof, and the organic compound and the first bonding compound are combined via a urea reaction.

### CROSS-REFERENCE TO RELATED APPLICATIONS

This U.S. non-provisional patent application claims priority under 35 U.S.C. § 119 of Korean Patent Application No. 10-2025-0023152, filed on Feb. 21, 2025, and Korean Patent Application No. 10-2026-0020821, filed on Feb. 2, 2026, the entire contents of each of which are hereby incorporated by reference.

### BACKGROUND

### 1. Field of the Invention

The present disclosure relates to a protective film and an optical article including the same, and more particularly, to an anti-contamination and anti-reflection protective film, an optical article including the same, and a method for preparing the protective film.

### 2. Description of Related Art

Protective films for an optical article are required to prevent reflection of a display portion of the optical article caused by external light sources and prevent external contamination such as fingerprints, thereby continuously delivering clear images. Accordingly, the protective films require a surface having low visible light reflectance for anti-reflection properties and high hydrophobicity (i.e., a high water contact angle) for anti-contamination properties. In addition, the protective films need to exhibit both excellent friction resistance and flexibility to extend the lifespan of optical articles and to be applicable to flexible optical articles such as flexible displays. Furthermore, to achieve cost reduction, the protective films need to be prepared through a solution coating process rather than a vacuum deposition process.

Typical protective films for an optical article fail to simultaneously provide excellent performance in anti-contamination, anti-reflection, friction resistance, flexibility, and low cost in combination. Generally, protective films provide either anti-contamination or anti-reflection properties; thus, to achieve both anti-contamination and anti-reflection performance in combination, a high-cost protective film having a double-layer structure, in which an anti-contamination protective film is disposed on an anti-reflection protective film, is required. In this case, the anti-contamination protective film is prepared to have a single-layer structure of organic-inorganic composite materials through a solution coating process, which facilitates cost reduction and offers improved flexibility. Conversely, the anti-reflection protective film is prepared to have a multi-layer structure of inorganic materials through a vacuum deposition process, which hinders cost reduction and results in limited flexibility. While anti-reflection protective films having a single-layer structure of organic-inorganic composite materials using a solution coating process have been studied, such films exhibit high visible light reflectance and suffer from degraded friction resistance at an upper anti-contamination film portion.

### SUMMARY

The present disclosure provides a protective film for an optical article, configured to exhibit both excellent anti-reflection and anti-contamination properties.

The present disclosure also provides a protective film for an optical article, configured to provide improved friction resistance, flexibility, and applicability to a solution coating process.

An embodiment of the inventive concept provides a protective film including a substrate including a first surface and a second surface facing each other, and a film portion disposed on the first surface, wherein the film portion includes first particles and an organic compound that interconnects the first particles, the first particles include all of a first inorganic particle and a first bonding compound and a first hydrophobic compound disposed on a surface of the first inorganic particle, the organic compound includes an aliphatic polyisocyanate, the first bonding compound is selected from the group consisting of a compound having a secondary amine group (—NH), a compound having an imine group (—C═N), and a combination thereof, the first hydrophobic compound is selected from the group consisting of a compound having a methyl group (—CH₃), a compound having a trifluoromethyl group (—CF₃), and a combination thereof, and the isocyanate group (—NCO) of the organic compound and the secondary amine group (—NH) and the imine group (—C═N) of the first bonding compound are bonded via a urea reaction.

In an embodiment of the inventive concept, an optical article includes a display portion, and a protective film on the display portion, wherein the protective film includes a substrate including a first surface and a second surface facing each other, and a film portion disposed on the first surface, the film portion includes first particles and an organic compound that interconnects the first particles, the first particles include a first inorganic particle and a first bonding compound and a first hydrophobic compound disposed on a surface of the first inorganic particle, the organic compound includes an aliphatic polyisocyanate, the first bonding compound is selected from the group consisting of a compound having a secondary amine group, a compound having an imine group, and a combination thereof, the first hydrophobic compound is selected from the group consisting of a compound having a methyl group, a compound having a trifluoromethyl group, and a combination thereof, and the isocyanate group of the organic compound and the secondary amine group and the imine group of the first bonding compound are bonded via a urea reaction.

In an embodiment of the inventive concept, a method for preparing a protective film includes preparing a first substance containing an organic compound and a second substance containing a first particle, mixing the first substance and the second substance in a solvent to prepare a composition for a protective film, and applying the composition for a protective film to form a film portion, wherein the preparing of the second substance includes preparing a first inorganic particle and surface-treating a surface of the first inorganic particle with a first bonding compound and a first hydrophobic compound, the organic compound includes an aliphatic polyisocyanate, the first bonding compound is selected from the group consisting of a compound having a secondary amine group, a compound having an imine group, and a combination thereof, the first hydrophobic compound is selected from the group consisting of a compound having a methyl group, a compound having a trifluoromethyl group, and a combination thereof, and in a solid content of the composition for a protective film, the first inorganic particle is present in an amount of about 30 wt % to about 45 wt % by weight, an equivalent ratio of a secondary amine group and an imine group of the second substance to an isocyanate group of the first substance is about 1:1, and a molar ratio of the first bonding compound to the first hydrophobic compound is about 1:1 to about 1:2.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a protective film according to embodiments of the inventive concept;

FIG. 2 is a view enlarging M of FIG. 1;

FIG. 3 is a view enlarging M of FIG. 1 according to some embodiment of the inventive concept;

FIG. 4 is a view enlarging M of FIG. 1 according to some embodiment of the inventive concept;

FIG. 5 is a cross-sectional view of an optical article according to some embodiments of the inventive concept;

FIGS. 6 and 7 are flowcharts showing a method for preparing a protective film according to embodiments of the inventive concept; and

FIG. 8 is a flowchart showing a method for preparing a protective film according to some embodiments of the inventive concept.

### DETAILED DESCRIPTION OF THE INVENTION

Hereinafter, the present disclosure will be described in detail by describing embodiments of the inventive concept with reference to attached drawings.

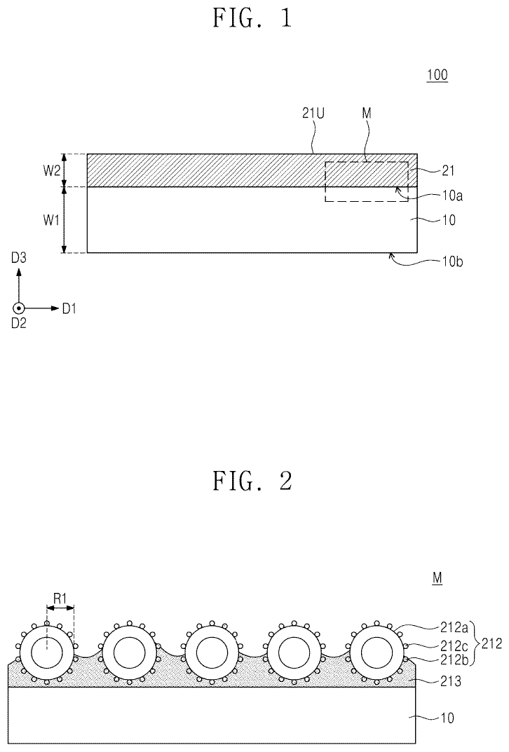

FIG. 1 is a cross-sectional view of a protective film according to embodiments of the inventive concept. FIG. 2 is a view enlarging M of FIG. 1.

Referring to FIGS. 1 and 2, a protective film 100 according to embodiments of the inventive concept may include a substrate 10 and a film portion 21. The film portion 21 may be disposed on the substrate 10. The substrate 10 may include a first surface 10a and a second surface 10b facing each other. The film portion 21 may be disposed on the first surface 10a of the substrate 10.

The substrate 10 may include at least one of a cover window, an optical window, or an optical lens. The substrate 10 may include a polymer, and the polymer may be transparent. The substrate may include at least one of polyethylene terephthalate, colorless polyimide, thermoplastic polyurethane, polycarbonate, and polymethyl methacrylate. The substrate 10 may have excellent impact resistance. The substrate 10 may have a thickness W1 of about 50 μm to about 150 μm. The substrate 10 may have a refractive index of about 1.45 to about 1.65. The thickness in this specification may refer to a value measured in a third direction D3 perpendicular to the first surface 10a of the substrate 10.

The substrate 10 may have a visible light transmittance of about 90% or greater, and have a visible light reflectance of about 4% or greater at the substrate surface 10a. The substrate surface 10a may be hydrophilic, and have a water contact angle of less than about 90° on the surface.

The film portion 21 may have a thickness W2 of about 60 nm to about 160 nm. A refractive index of the film portion 21 may have a value between a refractive index of the substrate 10 and a refractive index of air. The film portion 21 may have a refractive index of about 1.2 to about 1.4. The thickness W2 of the film portion 21 may increase as a difference between the refractive index of the substrate 10 and the refractive index of the film portion 21 increases. A visible light reflectance at a surface 21U of the film portion 21 may be about 2% or less. A water contact angle of the surface 21U of the film portion 21 may be about 100° to about 125°.

The film portion 21 may include first particles 212 and an organic compound 213 that interconnects the first particles 212. The organic compound 213 may cover a portion of a surface of the first particles 212. The first particles 212 may be evenly distributed within the organic compound 213. The first particles 212 may include a first inorganic particle 212a, a first bonding compound 212b disposed on a surface of the first inorganic particle 212a, and a first hydrophobic compound 212c. The surface of the first particles 212 on which the first bonding compound 212b is disposed may be in contact with the organic compound 213, and the surface of the first particles 212 on which the first hydrophobic compound 212c is disposed may be exposed to the air.

A content of the first inorganic particles 212a in the film portion 21 may be about 30 wt % to about 45 wt % with respect to 100 wt % of the film portion. When the content of the first inorganic particles 212a is less than about 30 wt %, anti-reflection performance may be degraded, and when the content is greater than about 45 wt %, friction resistance and flexibility may be degraded. That is, when the content of the first inorganic particles 212a satisfies the above numerical range, a protective film exhibiting excellent friction resistance, flexibility, and anti-reflection properties may be provided.

The organic compound 213 may include polyisocyanate. The polyisocyanate may be aliphatic rather than aromatic. That is, the organic compound 213 may include an aliphatic polyisocyanate. Accordingly, yellowing and chalking of the protective film, caused by exposure to ultraviolet rays, may be prevented. Furthermore, the protective film may maintain high visible light transmittance even after prolonged use.

The aliphatic polyisocyanate may include a hexamethylene diisocyanate oligomer. The hexamethylene diisocyanate oligomer may be selected from the group consisting of uretdione, a compound of Formula 1 below, biuret, a compound of Formula 2 below, isocyanurate, a compound of Formula 3 below, and a combination thereof.

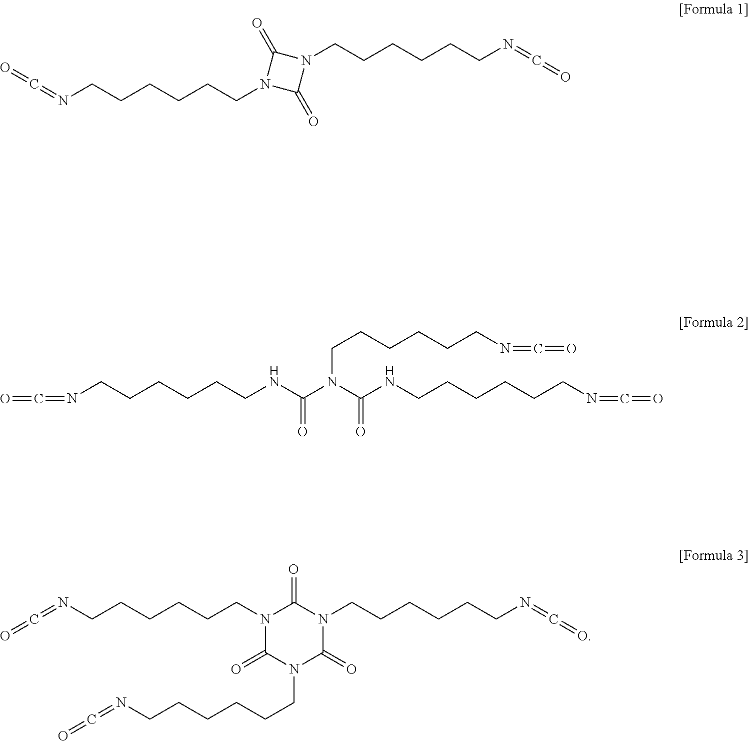 [SMILES: O=C=NCCCCCCN1C(=O)N(CCCCCCN=C=O)C1=O ; O=C=NCCCCCCNC(=O)N(CCCCCCN=C=O)C(=O)NCCCCCCN=C=O ; O=C=NCCCCCCn1c(=O)n(CCCCCCN=C=O)c(=O)n(CCCCCCN=C=O)c1=O]

The organic compound 213 may further include a polyaspartic ester in addition to an aliphatic polyisocyanate. The aliphatic polyisocyanate and the polyaspartic ester contained in the organic compound 213 may be bonded to each other via a urea reaction.

The polyaspartic ester may be selected from the group consisting of aspartic acid, N,N′-(methylenedi-4,1-cyclohexanediyl)bis-, tetraethyl ester represented by Formula 4; aspartic acid, N,N-methylenebis(2-methyl-4,1-cyclohexanediyl)bis-, tetraethyl ester represented by Formula 5; and a combination thereof.

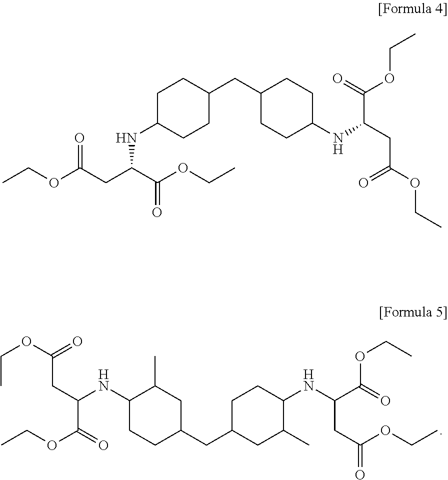

The first inorganic particle 212a may include hollow silica having an empty particle interior. The first inorganic particle 212a may be spherical and have an outer radius R1 of about 20 nm to about 50 nm. When the outer radius R1 of the first inorganic particle 212a falls outside the above numerical range, anti-reflection properties may be degraded. The first inorganic particle 212a may have a hollowness, i.e., a volume ratio of an internal empty space to a total volume of particles, of about 30 vol % to about 50 vol %. When the hollowness of the first inorganic particle 212a is less than about 30 vol %, the refractive index may increase, thereby degrading anti-reflection properties. When the hollowness of the first inorganic particle 212a is greater than about 50 vol %, the refractive index may decrease, but the physical stability of the first inorganic particle 212a and the resulting performance stability of the protective film may be degraded.

The first bonding compound 212b disposed on a surface of the first inorganic particle 212a may be selected from a compound having a secondary amine group (—NH), a compound having an imine group (—C═N), and a combination thereof. The secondary amine group (—NH) and the imine group (—C═N) of the first bonding compound 212b may be bonded to the isocyanate group (—NCO) of the aliphatic polyisocyanate contained in the organic compound 213 via a urea reaction. Accordingly, the first inorganic particle 212a may be uniformly dispersed within the organic compound 213, and bonding strength between the organic compound 213 and the first inorganic particle 212a may be enhanced. Therefore, the protective film may exhibit anti-reflection properties and friction resistance.

The first hydrophobic compound 212c disposed on the surface of the first inorganic particle 212a may be selected from a compound having a methyl group (—CH₃), a compound having a trifluoromethyl group (—CF₃), and a combination thereof. The first hydrophobic compound 212c may have strong hydrophobicity and may be exposed to the surface 21U of the film portion 21. The water contact angle on the surface 21U of the film portion 21 may be as high as about 100° to about 125°, and may exhibit excellent anti-contamination properties.

A weight ratio of the first inorganic particle 212a to a sum of the first bonding compound 212b and the first hydrophobic compound 212c may be about 1:0.7 to about 1:1.4. When the weight ratio of the first inorganic particle 212a to a sum of the first bonding compound 212b and the first hydrophobic compound 212c is less than about 1:0.7, friction resistance and anti-contamination properties may be degraded, and when the weight ratio is greater than about 1:1.4, anti-reflection properties may be degraded.

A molar ratio of the first bonding compound 212b to the first hydrophobic compound 212c may be about 1:1 to about 1:2. When a ratio of the number of moles of the first bonding compound 212b to the number of moles of the first hydrophobic compound 212c is less than about 1:1, anti-contamination properties may be degraded.

Each of the first bonding compound 212b and the first hydrophobic compound 212c may be selected from a silane coupling agent having a methoxy group (—OCH₃), a silane coupling agent having an ethoxy group (—OC₂H₅), and a combination thereof. The methoxy group (—OCH₃) and the ethoxy group (—OC₂H₅) of the first bonding compound 212b and the first hydrophobic compound 212c may be chemically bonded to a hydroxyl group (—OH) on the surface of the first inorganic particle 212a via hydrolysis and condensation reactions.

The first bonding compound 212b may be a silane coupling agent having a secondary amine group (—NH). When the first bonding compound 212b has a primary amine group (—NH₂), a urea reaction with the isocyanate group (—NCO) of the aliphatic polyisocyanate contained in the organic compound 213 may be too rapid, making it difficult to prepare a coating composition for a protective film. When the first bonding compound 212b has a tertiary amine group (—N), it may be difficult to initiate a urea reaction with the isocyanate group (—NCO) of the aliphatic polyisocyanate.

The silane coupling agent having a secondary amine group (—NH) may be, for example, N-ethyl-3-trimethoxysilyl-2-methylpropanamine of Formula 6 below. Compared to other silane coupling agents having a secondary amine group (—NH), such as N-butylaminopropyltrimethoxysilane, bis(3-trimethoxysilylpropyl) amine, and N,N′-bis[3-(trimethoxysilyl)propyl]ethylenediamine, N-ethyl-3-trimethoxysilyl-2-methylpropanamine exhibits a sufficiently slow urea reaction with the isocyanate group (—NCO) of the aliphatic polyisocyanate included in the organic compound 213, which may facilitate the preparation of a coating composition for a protective film.

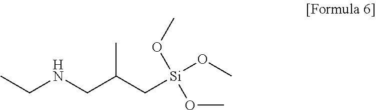

The first bonding compound 212b may be a silane coupling agent having an imine group (—C═N). The silane coupling agent having an imine group (—C═N) may be, for example, N-[3-(triethoxysilylpropyl)] benzaldehyde imine of Formula 7 below. Compared to other silane coupling agents having an imine group (—C═N), such as 3-triethoxysilyl-N-(1,3 dimethyl-butylidene) propylamine, N-[3-(triethoxysilylpropyl)] benzaldehyde imine exhibits a sufficiently slow urea reaction with the isocyanate groups (—NCO) of the aliphatic polyisocyanate included in the organic compound 213, which facilitates the preparation of a coating composition for a protective film.

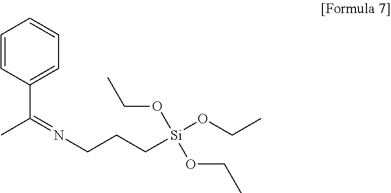 [SMILES: CCO[Si](CCCN=C(C)c1ccccc1)(OCC)OCC]

Accordingly, the first bonding compound 212b may be selected from the group consisting of N-ethyl-3-trimethoxysilyl-2-methylpropanamine of Formula 6, N-[3-(triethoxysilylpropyl)] benzaldehyde imine of Formula 7, and a combination thereof.

The first hydrophobic compound 212c may be selected from the group consisting of a hydrophobic silane coupling agent having a methyl group (—CH₃), a hydrophobic silane coupling agent having a trifluoromethyl group (—CF₃), and a combination thereof. When the first hydrophobic compound 212c has a methyl group (—CH₃), the compound may be less harmful to the human body and be environmentally friendly. When the first hydrophobic compound 212c has a trifluoromethyl group (—CF₃), the water contact angle on the surface 21U of the film portion 21 increases, thereby improving anti-contamination properties.

The hydrophobic silane coupling agent having a methyl group (—CH₃) may be selected from the group consisting of, for example, dodecyltrimethoxysilane, dodecyltriethoxysilane, hexadecyltrimethoxysilane, hexadecyltriethoxysilane, octadecyltrimethoxysilane, octadecyltriethoxysilane, and a combination thereof. These agents have sufficiently long alkyl chain length (the number of carbon atoms bonded to hydrogen atoms) of about 12 to about 18, and thus may exhibit stronger hydrophobicity than other silane coupling agents having a methyl group (—CH₃) with an alkyl chain length of less than about 12. Accordingly, these agents are favorable for improving the anti-contamination properties on the surface 21U of the film portion 21.

The hydrophobic silane coupling agents having a trifluoromethyl group (—CF₃) may be selected from the group consisting of, for example, 1H, 1H,2H,2H-perfluorooctyltrimethoxysilane, 1H, 1H,2H,2H-perfluorooctyltriethoxysilane, heptadecafluoro-1,1,2,2 tetrahydrodecyltrimethoxysilane, heptadecafluoro-1,1,2,2 tetrahydrodecyltriethoxysilane, and a combination thereof. These silane coupling agents have a sufficiently long fluoroalkyl chain length of about 6 to about 8, and thus may exhibit stronger hydrophobicity than other silane coupling agents having a trifluoromethyl group (—CF₃) with a fluoroalkyl chain length (the number of carbon atoms bonded to fluorine atoms) of less than about 6. Accordingly, these agents are favorable for improving the anti-contamination properties on the surface 21U of the film portion 21.

Accordingly, the first hydrophobic compound 212c may be selected from the group consisting of dodecyltrimethoxysilane, dodecyltriethoxysilane, hexadecyltrimethoxysilane, hexadecyltriethoxysilane, octadecyltrimethoxysilane, octadecyltriethoxysilane, 1H, 1H,2H,2H-perfluorooctyltrimethoxysilane, 1H,1H,2H,2H-perfluorooctyltriethoxysilane, heptadecafluoro-1,1,2,2 tetrahydrodecyltrimethoxysilane, heptadecafluoro-1,1,2,2 tetrahydrodecyltriethoxysilane, and a combination thereof.

The film portion 21 according to the inventive concept may include the first particles 212 and the organic compound 213 that interconnects the first particles 212. The first particles 212 may include all of the first inorganic particle 212a including hollow silica having a low refractive index, the first bonding compound 212b disposed on the surface thereof, and the first hydrophobic compound 212c. The secondary amine group (—NH) and the imine group (—C═N) of the first bonding compound 212b may be bonded to the isocyanate group (—NCO) of the organic compound 213 via a urea reaction. The first hydrophobic compound 212c is a strongly hydrophobic substance containing a methyl group (—CH₃) and a trifluoromethyl group (—CF₃), and is exposed on the surface 21U of the film portion 21. This provides a protective film having a combination of anti-reflection properties, flexibility, friction resistance, and anti-contamination properties.

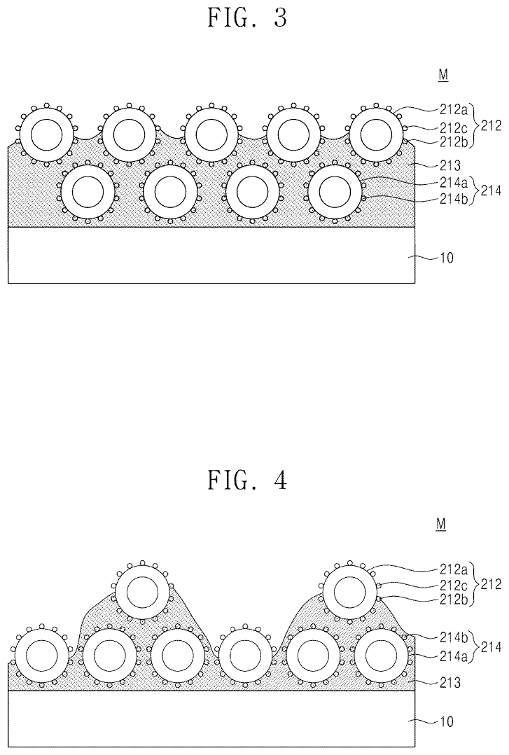

FIG. 3 is a view enlarging M of FIG. 1 according to some embodiment of the inventive concept. FIG. 4 is a view enlarging M of FIG. 1 according to some embodiment of the inventive concept. For conciseness, descriptions overlapping with the above descriptions provided with reference to FIGS. 1 and 2 will not be provided.

Referring to FIG. 3, the film portion 21 may further include second particles 214 in addition to the first particles 212 and the organic compound 213 that interconnects the first particles 212. The second particles 214 may include a second inorganic particle 214a and a second bonding compound 214b disposed on a surface of the second inorganic particle 214a. The second particles 214 are distinguished from the first particles 212 in that the second particles 214 do not include a hydrophobic compound on the surface of the inorganic particle. The first particles 212 and the second particles 214 may be evenly distributed within the organic compound 213. The second particles 214 may be disposed below the first particles 212. The organic compound 213 may cover the second particles 214, and the second particles 214 may be evenly distributed within the organic compound 213. Regarding the second particles 214, only the second bonding compound 214b is disposed on the second inorganic particle 214a, and thus the second particles 214 may exhibit excellent bonding strength with the organic compound 213. A surface of the second particles 214 may be in contact with the organic compound 213.

By further including the second particles 214 in the film portion 21, the thickness W2 of the film portion 21 may be more easily controlled to reach an appropriate range, i.e., about 60 nm to about 160 nm. In addition, the adhesion and friction resistance of the substrate surface 10a in contact with the film portion 21 may be enhanced.

The first particles 212 may be disposed on the second particles 214. At least a portion of the surface of the first particles 212 may be exposed to the air. The surface of the first particles 212 on which the first hydrophobic compound 212c is disposed may be exposed to the air. The surface of the first particles 212 on which the first bonding compound 212b is disposed may be bonded to an organic compound.

The content of the first inorganic particle 212a and the second inorganic particle 214a in the film portion 21 may be about 30 wt % to about 45 wt % by weight. A weight ratio of the first inorganic particle 212a to the second inorganic particle 214a may be about 1:0.5 to about 1:1. When the ratio of the weight of the first inorganic particle 212a to the weight of the second inorganic particle 214a is less than about 1:0.5, the adhesion and friction resistance between the film portion 21 and the substrate surface 10a may be degraded. When the ratio of the weight of the first inorganic particle 212a to the weight of the second inorganic particle 214a is greater than about 1:1, the amount of the first particles 212 included in the film portion 21 decreases, and accordingly, the amount of the hydrophobic first hydrophobic compound 212c included in the first particles 212 exposed to the surface 21U of the film portion 21 decreases, which may result in degraded anti-contamination properties.

A weight ratio of the second inorganic particle 214a to the second bonding compound 214b may be about 1:0.5 to about 1:1. When the ratio of the weight of the second inorganic particle 214a to the weight of the second bonding compound 214b is less than about 1:0.5, the adhesion and friction resistance between the film portion 21 and the substrate surface 10a may be degraded. When the ratio of the weight of the second inorganic particle 214a to the weight of the second bonding compound 214b is greater than about 1:1, anti-reflection properties may be degraded.

The second inorganic particle 214a and the second bonding compound 214b may be substantially identical to the first inorganic particle 212a and the first bonding compound 212b described with reference to FIGS. 1 and 2.

Referring to FIG. 4, the first particles 212 and the second particles 214 may be disposed in various forms. The first particles 212 may be disposed next to the second particles 214 or may be disposed on the second particles 214. The organic compound 213 may cover the second particles 214 and may cover a surface of the first particles 212 on which the first bonding compound 212b is disposed. A portion of the surface of the first particles 212 may be exposed to the air. Of the surface of the first particles 212a, a surface on which the first hydrophobic compound 212c is disposed may be exposed to the air.

Other structures may be substantially the same as the structures described with reference to FIGS. 1 and 2.

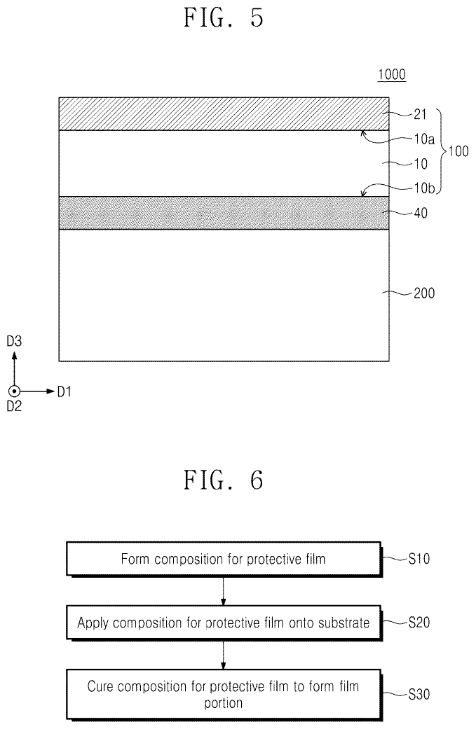

FIG. 5 is a cross-sectional view of an optical article according to some embodiments of the inventive concept. For conciseness, descriptions overlapping with the above descriptions provided with reference to FIGS. 1 and 2 will not be provided.

Referring to FIG. 5, an optical article 1000 may include a protective film 100, a display portion 200, and an optically clear resin (OCR) layer 40. The protective film 100 may be disposed on the display portion 200. The optically clear resin layer 40 may be interposed between the substrate 10 of the protective film 100 and the display portion 200. The optically clear resin layer 40 may be in contact with a second surface 10b of the substrate 10 of the protective film 100. The display portion 200 and the protective film 100 may be mechanically connected through the optically clear resin layer 40.

The display portion 200 may include an organic light emitting diode (OLED) or a micro light emitting diode. The display portion 200 may display images. Instead of the optically clear resin layer 40, an optically clear adhesive (OCA) layer may be used. The protective film 100 may correspond to the protective film 100 (FIG. 1) described with reference to FIG. 1.

Other configurations may be substantially the same as those described with reference to FIGS. 1 and 2.

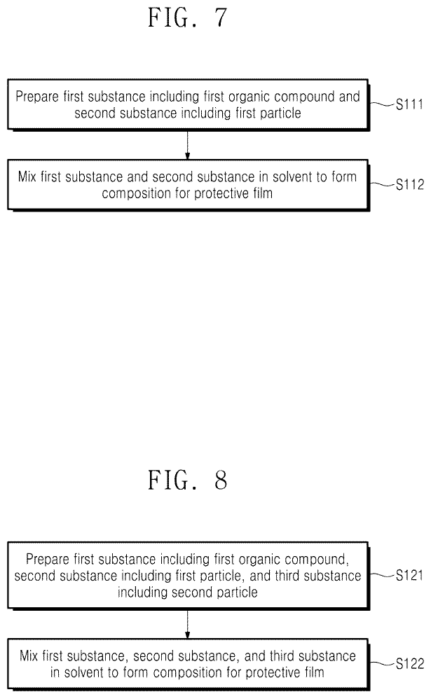

FIGS. 6 and 7 are flowcharts showing a method for preparing a protective film according to embodiments of the inventive concept. For conciseness, descriptions overlapping with the above descriptions provided with reference to FIGS. 1 and 2 will not be provided.

Referring to FIG. 6, a method for preparing a protective film may include forming a composition for a protective film (S10), applying the composition for a protective film onto a substrate (S20), and curing the composition for a protective film to form a film portion (S30).

Referring to FIG. 7, the forming of the composition for a protective film (S10) may include preparing a first substance including an organic compound 213 and a second substance including first particles 212 (S111), and mixing the first substance and the second substance in a solvent to form a composition for a protective film (S112).

The preparing of the first substance may include preparing an organic compound and dissolving the organic compound in a solvent. The organic compound may correspond to the organic compound described with reference to FIGS. 1 and 2.

The preparing of the second substance may include preparing a first inorganic particle, dispersing the first inorganic particle in a solvent, and adding a first bonding compound and a first hydrophobic compound to a colloidal solution in which the first inorganic particle is dispersed in the solvent and bonding the mixture to a surface of the first inorganic particle for surface treatment. The ratio of weight of the first inorganic particle to the weight of the first bonding compound and the first hydrophobic compound may be about 1:0.7 to about 1:1.4. A molar ratio of the first bonding compound to the first hydrophobic compound may be about 1:1 to about 1:2. The first inorganic particle, the first hydrophobic compound, and the first bonding compound may correspond to the first inorganic particle, the first hydrophobic compound, and the first bonding compound described with reference to FIGS. 1 and 2.

The solvent may be, for example, propylene glycol methyl ether acetate (PGMEA), isopropyl alcohol, or ethyl alcohol. The solvent has sufficiently high solubility for the aliphatic polyisocyanate and polyaspartic ester that may be included in the organic compound and sufficiently high dispersibility for hollow silica particles, which may prevent the formation of precipitates.

The forming of a colloidal solution by dispersing the first inorganic particle in a solvent and the surface-treating of the surface of the first inorganic particle with a first bonding compound and a first hydrophobic compound may be performed while applying ultrasonic waves.

The forming of a composition for a protective film by mixing the first and second substances in a solvent (S112) may have an equivalent ratio of about 1:1 between an isocyanate group (—NCO) of the first substance and a secondary amine group (—NH) and an imine group 1 (—C═N) of the second substance. A weight of the first inorganic particle included in the second substance may be about 30 wt % to about 45 wt % with respect to a total weight of solids in the first and second substances, excluding the solvent.

Referring back to FIG. 6, the applying of the composition for a protective film onto a substrate (S20) may include a process of slot-die coating, spray coating, or spin coating.

The curing of the composition for a protective film to form a film portion (S30) may include heat-treating the composition for a protective film on a substrate. The heat treatment process may be performed at a pressure of about 0.1 Torr to about 760 Torr and a temperature of about 50° C. to about 80° C.

The solvent in the composition for a protective film may be dried and removed through the heat treatment process. The heat treatment process may be performed at a lower temperature as the boiling point of the solvent decreases, and may be performed at a lower temperature as the pressure of the heat treatment process decreases.

Through the heat treatment process, urea bonds may be formed between the isocyanate groups (—NCO) of the organic compound included in the first substance and the secondary amine group (—NH) and the imine group (—C═N) of the first bonding compound included in the second substance. Accordingly, the first particles and the organic compound may be interconnected, resulting in increased bonding strength. A film portion may be formed through the heat treatment process.

FIG. 8 is a flowchart showing a method for preparing a protective film according to some embodiments of the inventive concept. For conciseness, descriptions overlapping with the above descriptions provided with reference to FIGS. 1 and 2 will not be provided.

Referring to FIGS. 6 and 8, the forming of a composition for a protective film (S10) may include preparing a first substance including a first organic compound, a second substance including first particles, and a third substance including second particles (S121), and mixing the first substance, the second substance, and the third substance in a solvent to form a composition for a protective film (S122).

The preparing of the third substance may include preparing a second inorganic particle, dispersing the second inorganic particle in a solvent, and adding a second bonding compound to a colloidal solution in which the second inorganic particle is dispersed and bonding the compound to a surface of the second inorganic particle for surface treatment. A ratio of the weight of the second inorganic particle to the weight of the second bonding compound may be about 1:0.5 to about 1:1. The second particles, the second inorganic particle, and the second bonding compound may correspond to the second particles, the second inorganic particle, and the second bonding compound described with reference to FIGS. 1, 3, and 4.

The forming of the composition for a protective film by mixing the first, second, and third substances in a solvent (S122) may have an equivalent ratio of about 1:1 between an isocyanate group (—NCO) of the first substance and a secondary amine group (—NH) and an imine group 1 (—C═N) of the second substance and the third substance. A weight of the first and second inorganic particles included in the second and third substances may be about 30 wt % to about 45 wt % with respect to a total weight of solids in the first, second, and third substances, excluding the solvent. A weight ratio of the first inorganic particle of the second substance to the second-inorganic particle of the third substance may be about 1:0.5 to about 1:1.

Other preparation processes may be substantially the same as those described with reference to FIGS. 6 and 7.

Hereinafter, the inventive concept will be described through Examples.

### EXAMPLES

An organic compound containing isocyanurate was prepared and dissolved in a PGMEA solvent to prepare a first substance. A first inorganic particle including hollow silica particles having an outer radius of 30 nm and a hollowness of 30 vol % was prepared and dispersed in a PGMEA solvent, and the resulting product was then surface-treated with first a bonding compound containing N-[3-(triethoxysilylpropyl)] benzaldehyde imine and a first hydrophobic compound containing hexadecyltrimethoxysilane to prepare a second substance. In this case, a weight ratio of the first inorganic particle to the first bonding compound and the first hydrophobic compound was 1:1.1. In addition, a molar ratio of the first bonding compound to the first hydrophobic compound was 1:1.5. A second inorganic particle including hollow silica particles having an outer radius of 30 nm and a hollowness of 30 vol %, was dispersed in a PGMEA solvent, and the resulting product was then surface-treated with a second bonding compound containing N-ethyl-3-trimethoxysilyl-2-methylpropanamine to prepare a third substance. In this case, a weight ratio of the second bonding compound to the second inorganic particle was 1:0.5.

The first, second, and third substances were mixed in a PGMEA solvent to form a composition for a protective film. In this case, the molar ratio of an isocyanate group (—NCO) of the first substance to an imine group 1 (—C═N) of the second substance and a secondary amine group (—NH) of the third substance were 1:1. In addition, a weight of the first inorganic particle of the second substance and the second inorganic particle of the third substance was 45 wt % with respect to a total weight of solids of the first, second, and third substances, excluding the solvent. A weight ratio of the first inorganic particle of the second substance to the second inorganic particle of the third substance was 1:0.7.

The composition for a protective film was then applied onto a polyethylene terephthalate substrate having a thickness of 50 μm through a spin coating process. Then, the resulting product was heat treated at a pressure of 0.1 Torr and a temperature of 60° C. to form a film portion. In this case, the film portion had a thickness of 90 nm.

### Evaluation Example

Visible light reflectance and water contact angle were measured before (Comparative Example) and after (Example) forming a film portion of Example on one surface of a substrate. Visible light reflectance was measured at a center wavelength of 550 nm, and water contact angle was measured by dropping several μL of deionized water. The results are shown in Table 1 below.

TABLE 1

| | Visible light | Water contact |
|---|---|---|
| Item | reflectance (%) | angle (°) |
| Comparative Example | 9.2 | 67 |
| Example | 5.5 | 113 |

Referring to Table 1, the visible light reflectance on one surface of the substrate decreased from 9.2% in Comparative Example to 5.5% according to the formation of the film portion of Example. In addition, the water contact angle on one surface of the substrate increased from 67° in Comparative Example to 113° in Example. That is, it is confirmed that the protective film exhibits excellent anti-reflection and anti-contamination properties according to the formation of the film portion of Example.

According to the inventive concept, a protective film is prepared from an organic-inorganic composite material including an organic compound, a first inorganic particle, a first bonding compound, and a first hydrophobic compound, and may thus be provided as a protective film exhibiting improved flexibility and applicability to a solution coating process.

In addition, the first inorganic particle and the organic compound constituting the protective film are strongly bonded to each other via a urea reaction between the first bonding compound disposed on a surface of the first inorganic particle and the organic compound, thereby providing a protective film exhibiting improved friction resistance.

Furthermore, the first inorganic particle dispersed within the protective film has a low refractive index, thereby providing a protective film exhibiting anti-reflection properties.

Moreover, a first hydrophobic compound having high hydrophobicity and disposed on the surface of the first inorganic particle is exposed to the air, thereby providing a protective film surface exhibiting anti-contamination properties.

In the above, embodiments of the inventive concept have been described with reference to the accompanying drawings, but those skilled in the art to which the inventive concept pertains may understand that various modifications and changes may be made to the inventive concept insofar as such modifications and changes do not depart from the spirit and scope of the inventive concept set forth in the claims to be described later. In addition, the embodiments disclosed in the inventive concept are not intended to limit the technical spirit of the inventive concept, and the scope of the disclosure is not to be limited by the above embodiments but by the claims and the equivalents thereof.

What is claimed is:

1. A protective film comprising:
a substrate comprising a first surface and a second surface facing each other; and
a film portion disposed on the first surface,
wherein the film portion comprises first particles and an organic compound that interconnects the first particles,
each of the first particles comprises a first inorganic particle and a first bonding compound and a first hydrophobic compound disposed on a surface of the first inorganic particle,
the organic compound comprises an aliphatic polyisocyanate,
the first bonding compound is selected from the group consisting of a compound having a secondary amine group, a compound having an imine group, and a combination thereof,
the first hydrophobic compound is selected from the group consisting of a compound having a methyl group, a compound having a trifluoromethyl group, and a combination thereof, and
the organic compound and the first bonding compound are combined via a urea reaction.

2. The protective film of claim 1, wherein the film portion further comprises second particles, and each of the second particles comprises a second inorganic particle and a second bonding compound disposed on a surface of the second inorganic particle, but does not include the first hydrophobic compound.

3. The protective film of claim 2, wherein a weight ratio of the first inorganic particle to the second inorganic particle is 1:0.5 to 1:1.

4. The protective film of claim 2, wherein a weight ratio of the second inorganic particle to the second bonding compound is 1:0.5 to 1:1.

5. The protective film of claim 2, wherein the first inorganic particle and the second inorganic particle comprise hollow silica particles.

6. The protective film of claim 5, wherein each of the first and second inorganic particles is spherical, and has an outer radius of 20 nm to 50 nm, and a hollowness of 30 vol % to 50 vol %.

7. The protective film of claim 1, wherein the aliphatic polyisocyanate comprises a hexamethylene diisocyanate oligomer.

8. The protective film of claim 1, wherein the aliphatic polyisocyanate is selected from the group consisting of a compound of Formula 1 below, a compound of Formula 2 below, a compound of Formula 3 below, and a combination thereof,

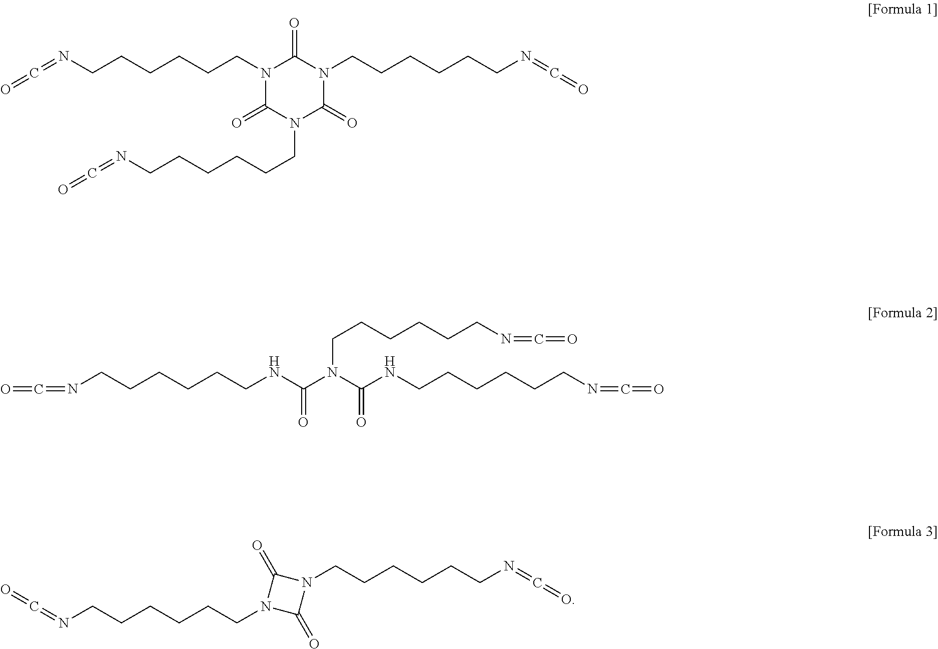 [SMILES: O=C=NCCCCCCn1c(=O)n(CCCCCCN=C=O)c(=O)n(CCCCCCN=C=O)c1=O ; O=C=NCCCCCCNC(=O)N(CCCCCCN=C=O)C(=O)NCCCCCCN=C=O ; O=C=NCCCCCCN1C(=O)N(CCCCCCN=C=O)C1=O]

9. The protective film of claim 1, wherein the organic compound further comprises a polyaspartic ester, and the polyaspartic ester is combined with the aliphatic polyisocyanate of the organic compound via a urea reaction.

10. The protective film of claim 9, wherein the polyaspartic ester is selected from the group consisting of a compound of Formula 4 below, a compound of Formula 5 below, and a combination thereof,

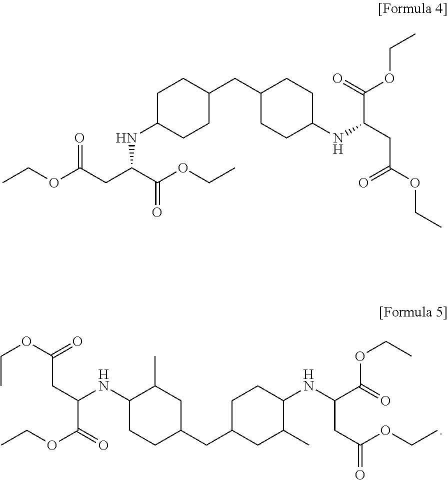

11. The protective film of claim 1, wherein each of the first bonding compound and the first hydrophobic compound is selected from the group consisting of a silane coupling agent having a methoxy group, a silane coupling agent having an ethoxy group, and a combination thereof.

12. The protective film of claim 1, wherein the first bonding compound is selected from the group consisting of a compound of Formula 6 below, a compound of Formula 7 below, and a combination thereof,

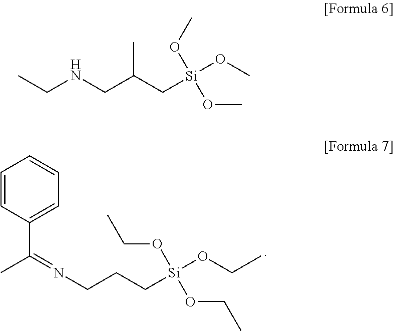

13. The protective film of claim 1, wherein the first hydrophobic compound is selected from the group consisting of dodecyltrimethoxysilane, dodecyltriethoxysilane, hexadecyltrimethoxysilane, hexadecyltriethoxysilane, octadecyltrimethoxysilane, octadecyltriethoxysilane, 1H,1H,2H,2H-perfluorooctyltrimethoxysilane, 1H,1H,2H,2H-perfluorooctyltriethoxysilane, heptadecafluoro-1,1,2,2 tetrahydrodecyltrimethoxysilane, heptadecafluoro-1,1,2,2 tetrahydrodecyltriethoxysilane, and a combination thereof.

14. The protective film of claim 2, wherein the first inorganic particle and the second inorganic particle are present in an amount of 30 wt % to 45 wt % with respect to 100 wt % of the film portion.

15. The protective film of claim 1, wherein in the first particles, a weight ratio of a weight of the first inorganic particle to a total weight of the first bonding compound and the first hydrophobic compound is 1:0.7 to 1:1.4.

16. The protective film of claim 1, wherein a molar ratio of the first bonding compound to the first hydrophobic compound is 1:1 to 1:2.

17. The protective film of claim 8, wherein an equivalent ratio of an isocyanate group of the organic compound to secondary amine and imine groups of the first bonding compound is 1:1.

18. The protective film of claim 1, wherein the film portion has a thickness of 60 nm to 160 nm.

19. An optical article comprising:
a display portion; and
a protective film on the display portion,
wherein the protective film includes:
a substrate including a first surface and a second surface facing each other; and
a film portion disposed on the first surface,
wherein the film portion includes first particles and an organic compound that interconnects the first particles,
each of the first particles includes a first inorganic particle and a first bonding compound and a first hydrophobic compound disposed on a surface of the first inorganic particle,
the organic compound includes an aliphatic polyisocyanate,
the first bonding compound is selected from the group consisting of a compound having a secondary amine group, a compound having an imine group, and a combination thereof,
the first hydrophobic compound is selected from the group consisting of a compound having a methyl group, a compound having a trifluoromethyl group, and a combination thereof, and
the organic compound and the first bonding compound are combined via a urea reaction.

20. A method for preparing a protective film, the method comprising:
preparing a first substance containing an organic compound and a second substance containing a first particle;
mixing the first substance and the second substance in a solvent to prepare a composition for a protective film; and
applying the composition for a protective film to form a film portion,
wherein the preparing of the second substance includes preparing a first inorganic particle and surface-treating a surface of the first inorganic particle with a first bonding compound and a first hydrophobic compound,
the organic compound includes an aliphatic polyisocyanate,
the first bonding compound is selected from the group consisting of a compound having a secondary amine group, a compound having an imine group, and a combination thereof,
the first hydrophobic compound is selected from the group consisting of a compound having a methyl group, a compound having a trifluoromethyl group, and a combination thereof,
in the composition for a protective film, the first inorganic particle is present in an amount of 30 wt % to 45 wt % by weight,
an equivalent ratio of a secondary amine group and an imine group of the second substance to an isocyanate group of the first substance is 1:1, and
a molar ratio of the first bonding compound to the first hydrophobic compound is 1:1 to 1:2.
